(19) United States
(12) Patent Application Publication
(10) Pub. No.: US 2023/0082085 A1
(43) Pub. Date: Mar. 16, 2023

(54) DISPLAY PANEL AND DISPLAY APPARATUS

(71) Applicant: WUHAN TIANMA MICRO-ELECTRONICS CO., LTD., Wuhan (CN)

(72) Inventors: Ai XIAO, Wuhan (CN); Linshan GUO, Wuhan (CN)

(73) Assignee: WUHAN TIANMA MICRO-ELECTRONICS CO., LTD., Wuhan (CN)

(21) Appl. No.: 18/056,948

(22) Filed: Nov. 18, 2022

(30) Foreign Application Priority Data
Jun. 30, 2022 (CN) 202210768681.0

(51) Int. Cl. H01L 51/52; H01L 27/32

(52) U.S. Cl. CPC H01L 51/5284; H01L 27/3246; G02B 5/201

(57) ABSTRACT

A display panel and a display apparatus are provided. A display region of the display panel includes a first display region and a second display region located between the first display region and the non-display region. The light-emitting device layer includes light-emitting devices which includes a first light-emitting device and a second light-emitting device. Light-blocking structures are located on a side of the light-emitting device layer away from the substrate and include a first light-blocking structure and a second light-blocking structure. The first light-blocking structure is adjacent to the first light-emitting device, and the second light-blocking structure is adjacent to the second light-emitting device. The first light-blocking structure has a greater thickness or height than the second light-blocking structure. The present disclosure can balance the brightness difference caused by different viewing angles at different display regions, improving visually uneven brightness and visual effect.

### CROSS-REFERENCE TO RELATED APPLICATION

The present application claims priority to Chinese Patent Application No. 202210768681.0, filed on Jun. 30, 2022, the content of which is incorporated herein by reference in its entirety.

### TECHNICAL FIELD

The present disclosure relates to the field of display technologies, and, particularly, relates to a display panel and a display apparatus.

### BACKGROUND

At present, there are two main display technologies such as liquid crystal display (LCD) and organic light-emitting display (OLED). OLED is based on recombination of electrons and holes in an organic material to emit light, so as to display different colors. An OLED device is a self-light-emitting device, which has characteristics such as a fast response speed, high brightness, wide viewing angle, low power consumption, and flexible display. The OLED device can meet the consumer's new requirements for display to be applied in currently mainstream display products. Current display products have a problem of uneven display brightness, affecting the display quality.

### SUMMARY

In a first aspect, an embodiment of the present disclosure provides a display panel. The display panel includes a display region, a non-display region, a substrate, a light-emitting device layer and light-blocking structures. The display region comprises a first display region and a second display region, and the second display region is located between the first display region and the non-display region. The light-emitting device layer is located on a side of the substrate. The light-emitting device layer includes light-emitting devices. Each of the light-emitting devices includes a first light-emitting device and a second light-emitting device. The first light-emitting device is located in the first display region, and the second light-emitting device is located in the second display region. The light-blocking structures are located on a side of the light-emitting device layer away from the substrate. Each of the light-blocking structures includes a first light-blocking structure and a second light-blocking structure. The first light-blocking structure is provided adjacent to the first light-emitting device, and the second light-blocking structure is provided adjacent to the second light-emitting device. A thickness of the first light-blocking structure is greater than a thickness of the second light-blocking structure, or a height of the first light-blocking structure is higher than a height of the second light-blocking structure.

In a second aspect, an embodiment of the present disclosure provides a display panel. The display panel includes a display region, a non-display region, a substrate, a light-emitting device layer, light-blocking structures and a color filter layer. The display region comprises a first display region and a second display region, and the second display region is located between the first display region and the non-display region. The light-emitting device layer is located on a side of the substrate. The light-emitting device layer includes light-emitting devices. Each of the light-emitting devices includes a first light-emitting device and a second light-emitting device. The first light-emitting device is located in the first display region, and the second light-emitting device is located in the second display region. The light-blocking structures are located on a side of the light-emitting device layer away from the substrate. Each of the light-blocking structures includes a first light-blocking structure and a second light-blocking structure. The first light-blocking structure is provided adjacent to the first light-emitting device, and the second light-blocking structure is provided adjacent to the second light-emitting device. The color filter layer is located on a side of the light-emitting device layer away from the substrate, and the color filter layer includes a black matrix and color filter units. The light-blocking structure includes a stacking structure consisting of the black matrix and color filter units of at least two colors. A width of an overlapping region of each of the color filter units in the first light-blocking structure is greater than a width of an overlapping region of each of the color filter units in the second light-blocking structure.

In a third aspect, a display apparatus is provided. The display apparatus includes the display panel described in the first and second aspects.

### BRIEF DESCRIPTION OF DRAWINGS

In order to more clearly explain the embodiments of the present disclosure or the technical solution in the related art, the drawings to be used in the description of the embodiments or the related art will be briefly described below. Obviously, the drawings in the following description are some embodiments of the present disclosure. For those skilled in the art, other drawings may also be obtained based on these drawings.

FIG. 1 is a schematic diagram of analysis of uneven display brightness in the related art;

FIG. 2 is a top view of a display panel according to an embodiment of the present disclosure;

FIG. 3 is an enlarged view of a region Z shown in FIG. 2 according to an embodiment of the present disclosure;

FIG. 4 is a cross-sectional view at the position of line A-A′ of FIG. 3 according to an embodiment of the present disclosure;

FIG. 5 is a schematic diagram of a display panel according to another embodiment of the present disclosure;

FIG. 6 is a schematic diagram of a display panel according to another embodiment of the present disclosure;

FIG. 7 is a schematic diagram of a display panel according to another embodiment of the present disclosure;

FIG. 8 is an enlarged view of the region Z shown in FIG. 2 according to another embodiment of the present disclosure;

FIG. 9 is a cross-sectional view at the position of line B-B′ shown in FIG. 8 according to an embodiment of the present disclosure;

FIG. 10 is a schematic diagram of a display panel according to another embodiment of the present disclosure;

FIG. 11 is a schematic diagram of a display panel according to another embodiment of the present disclosure;

FIG. 12 is a schematic diagram of a display panel according to another embodiment of the present disclosure;

FIG. 13 is a schematic diagram of a display panel according to another embodiment of the present disclosure;

FIG. 14 is a schematic diagram of a display panel according to another embodiment of the present disclosure;

FIG. 15 is a schematic diagram of a display panel according to another embodiment of the present disclosure;

FIG. 16 is a schematic diagram of a display panel according to another embodiment of the present disclosure;

FIG. 17 is a schematic diagram of a display panel according to another embodiment of the present disclosure;

FIG. 18 is a schematic diagram of a display panel according to another embodiment of the present disclosure;

FIG. 19 is a schematic diagram of a display panel according to another embodiment of the present disclosure;

FIG. 20 is a schematic diagram of a display panel according to another embodiment of the present disclosure;

FIG. 21 is a schematic diagram of a display panel according to another embodiment of the present disclosure;

FIG. 22 is a schematic diagram of a display panel according to another embodiment of the present disclosure;

FIG. 23 is a schematic diagram of a display panel according to another embodiment of the present disclosure;

FIG. 24 is a schematic diagram of a display panel according to another embodiment of the present disclosure; and

FIG. 25 is a schematic diagram of a display apparatus according to an embodiment of the present disclosure.

### DESCRIPTION OF EMBODIMENTS

In order to more clearly illustrate objectives, technical solutions, and advantages of the embodiments of the present disclosure, the technical solutions in the embodiments of the present disclosure are clearly and completely described in detail with reference to the accompanying drawings. Obviously, the described embodiments are merely part of the embodiments of the present disclosure rather than all of the embodiments. All other embodiments obtained by those skilled in the art based on the embodiments of the present disclosure shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

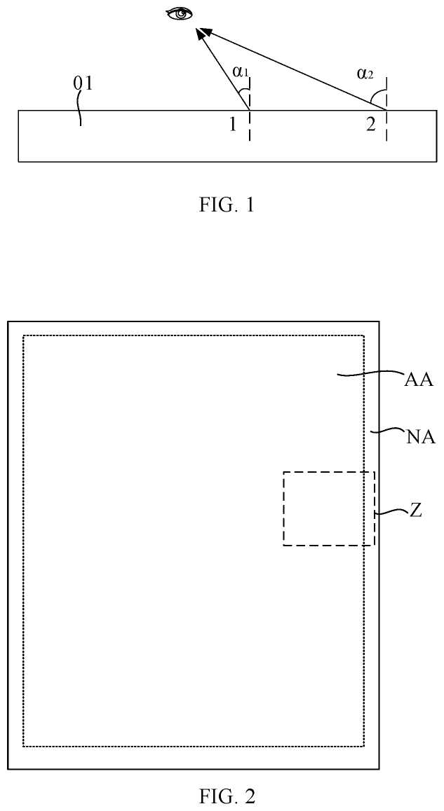

FIG. 1 is a schematic diagram of analysis of uneven display brightness in the related art. As shown in FIG. 1, when a display panel 01 is viewed by a human eye, viewing angles are different when different positions of the different display regions are viewed. When a human eye is fixed relative to the position of the display panel 01, the viewing angles α1 and α2 are formed at a viewing position 1 and a viewing position 2, respectively. Taking the viewing angle of position 1 as an example, the viewing angle is an angle formed between a connecting line passing through the human eye and position 1 of the display panel 01 and a direction from which the eye views straightly the position 1. When the position 1 is a flat plane, the direction from which the eye views straightly the position 1 is a direction perpendicular to the plane where the position 1 is located. When the position 1 is a curved plane, the direction from which the eye views straightly the position 1 is a direction perpendicular to a tangent plane of the curved plane where the position 1 is located. As shown in FIG. 1, α1 is less than α2, normally, the light emitted by position 1 is more received by the human eye compared to the light emitted by position 2, so that light amounts received by the human eye when viewing the position 1 and the position 2 are different, and there is a difference in the brightness visually perceived at the position 1 and the position 2, the final effect presented is uneven brightness of the display screen.

In order to solve the problems existing in the related art, the present disclosure provides a display panel. Different light-blocking structures are provided at different positions of the display region to balance the brightness difference caused by different viewing angles at different positions of the display region by using the light-blocking structures, so that the brightness received by the human eye when viewing different positions is substantially the same, thereby improving visually uneven brightness and visual effect.

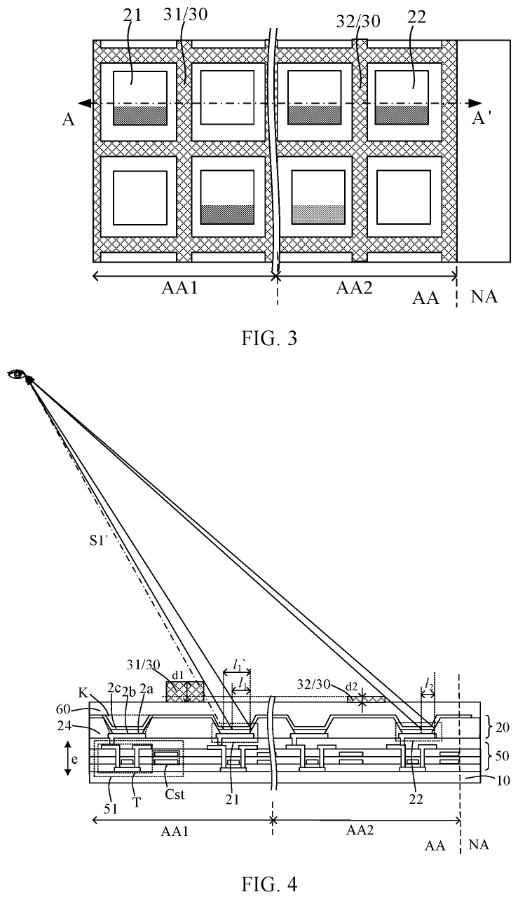

FIG. 2 is a top view of a display panel according to an embodiment of the present disclosure; FIG. 3 is an enlarged view of a region Z shown in FIG. 2 according to an embodiment of the present disclosure; and FIG. 4 is a cross-sectional view at the position of line A-A′ of FIG. 3 according to an embodiment of the present disclosure. As shown in FIG. 2, the display panel includes a display region AA and a non-display region NA.

As shown in FIG. 3, the display region AA includes a first display region AA1 and a second display region AA2. The second display region AA2 is located between the first display region AA1 and the non-display region NA. The display region AA includes a first light-emitting device 21 at a first display region AA1 and a second light-emitting device 22 at a second display region AA2. The display panel further includes a light-blocking structure 30. The light-blocking structure 30 includes a first light-blocking structure 31 and a second light-blocking structure 32. The first light-blocking structure 31 is provided adjacent to the first light-emitting device 21. The second light-blocking structure 32 is provided adjacent to the second light-emitting device 22. That is, the first light-blocking structure 31 is located in the first display region AA1, and the second light-blocking structure 32 is located in the second display region AA2.

As shown in FIG. 4, the display panel includes a substrate 10 and a light-emitting device layer 20. The light-emitting device layer 20 is located on a side of substrate 10. The first light-emitting device 21 and the second light-emitting device 22 are both located in the light-emitting device layer 20. The first light-emitting device 21 and the second light-emitting device 22 are classified by their positions in the display region. The first light-emitting device 21 and the second light-emitting device 22 each include a first electrode 2a, a light-emitting layer 2b and a second electrode 2c that are stacked. In an embodiment, the first light-emitting device 21 and the second light-emitting device 22 each include a red light-emitting device, a blue light-emitting device, and a green light-emitting device. In another embodiment, the first light-emitting device 21 and the second light-emitting device 22 are both a white light-emitting device.

The light-emitting device layer 20 further includes a pixel definition layer 24. The pixel definition layer 24 provides multiple openings K in which all light-emitting devices are located. It can be seen that the first light-emitting device 21 and the second light-emitting device 22 are both located in the opening K of pixel definition layer 24. The pixel definition layer 24 is used to separate adjacent light-emitting devices. The light-blocking structure 30 overlaps with the pixel definition layer 24, that is, the light-blocking structure 30 overlaps with the portion of the pixel definition layer 24 in which the opening K is not provided.

The light-blocking structure 30 is located on a side of light-emitting device layer 20 away from substrate 10. In a direction parallel to a plane of substrate 10, the first light-blocking structure 31 is located between adjacent first light-emitting device 21, and the second light-blocking structures 32 is located between adjacent second light-emitting devices 22.

In an embodiment, the display panel further includes an array layer 50 and a thin film encapsulation layer 60. The array layer 50 are located between the substrate 10 and the light-emitting device layer 20. The array layer 50 includes a pixel circuit 51. The pixel circuit 51 includes a thin film transistor T and a storage capacitor Cst. One electrode of the thin film transistor T is connected to the first electrode 2a of the light-emitting device. The pixel circuit 51 is configured to drive the light-emitting device to emit light. The thin film encapsulation layer 60 is located on a side of light-emitting device layer 20 away from substrate 10. The thin film encapsulation layer 60 is configured to encapsulate and protect the light-emitting device to ensure the service life of the light-emitting device. The light-blocking structure 30 is located on a side of the thin film encapsulation layer 60 away from substrate 10.

In the embodiments of the present disclosure, the light-blocking structure 30 has a function of blocking light. The light-blocking structure 30 is set to have a certain thickness in a direction e perpendicular to a plane of the substrate 10, or is set to have a certain height relative to the light-emitting device layer 20. The different thicknesses of the light-blocking structures 30 or different heights of the light-blocking structures 30 can achieve different light-blocking ability.

As shown in FIG. 4, the thickness d1 of the first light-blocking structure 31 is greater than the thickness d2 of the second light-blocking structure 32. The thickness of the light-blocking structure 30 can affect light emission of the adjacent light-emitting device. When the human eye views the display panel at the position shown in FIG. 4, a distance between the human eye and the first display region AA1 is greater than a distance between the human eye and the second display region AA2, so that the viewing angle by which the human eye views the first display region AA1 is less than the viewing angle by which the human eye views the second display region AA2.

A light emission range l₁ of the first light-emitting device 21 and a light emission range l₂ of the second light-emitting device 22 are schematically illustrated in FIG. 4. The light emitted by the first light-emitting device 21 in the light emission range l₁ can be received by the human eye, and the light emitted by the second light-emitting device 22 in the light emission range l₂ can be received by the human eye. Assuming that a thickness of the first light-blocking structure 31 is the same as a thickness of the second light-blocking structure 32, the light S1′ emitted by the first light-emitting device 21 (the light shown by a dotted line in FIG. 4) can also be received by the human eye, at this time, the light emission range of the first light-emitting device 21 is l₁′, it can be seen that the light emission range l₁′ is greater than the light emission range l₁, which means that more light emitted by the first light-emitting device 21 can be received by the human eye. In the embodiments of the present disclosure, the thickness of the first light-blocking structure 31 is increased, so that the thickness of the first light-blocking structure 31 is greater than the thickness of the second light-blocking structure 32. Therefore, the first light-blocking structure 31 blocks some light in the light emission range l₁′ toward the human eye, so that the light emission range of the first light-blocking structure 31 is reduced to the light emission range l₁. In the embodiments of the present disclosure, the first light-blocking structure 31 is used to reduce the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

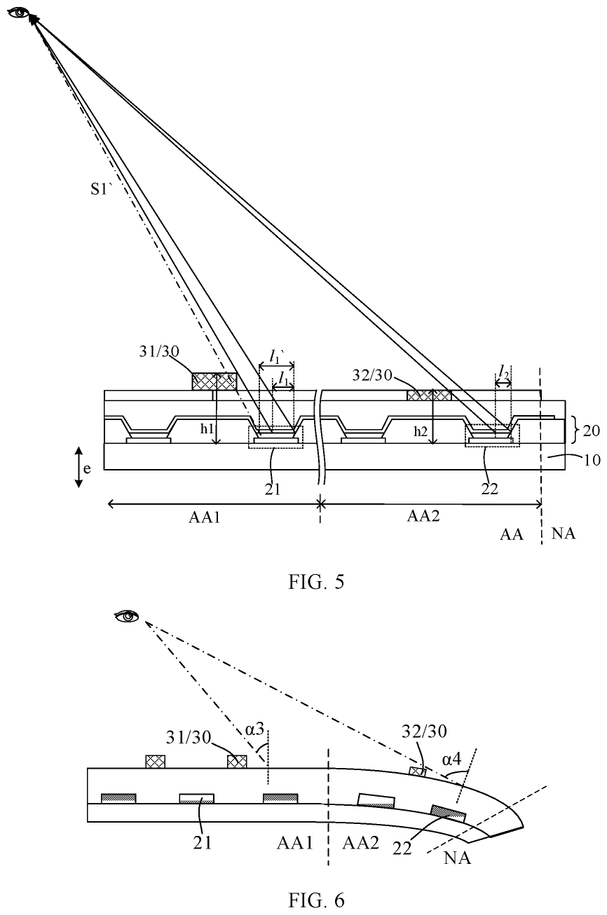

FIG. 5 is a schematic diagram of a display panel according to another embodiment of the present disclosure. In some other embodiments, as shown in FIG. 5, a height h1 of the first light-blocking structure 31 is higher than a height h2 of the second light-blocking structure 32. A comparison is performed with a same reference plane in the display panel layer when comparing the height of the first light-blocking structure 31 and the height of the second light-blocking structure 32. As illustrated in FIG. 5, a vertical distance between the surface of the first light-blocking structure 31 located on a side away from the substrate 10 and the substrate 10 is the height h1 of the first light-blocking structure 31, a vertical distance between the surface of the second light-blocking structure 32 located on a side away from the substrate 10 and the substrate 10 is the height h2 of the second light-blocking structure 32. The height of the light-blocking structure 30 can affect the light emission of its adjacent light-emitting devices. When the human eye views the display panel at the position shown in FIG. 5, the viewing angle of the human eye on the first display region AA1 is smaller than the viewing angle of the human eye on the second display region AA2. The eye viewing angle of the first display region AA1 is smaller than that of the second display region AA2. FIG. 5 shows the light emitting range l₁ of the first light-emitting device 21 and the light emitting range l₂ of the second light-emitting device 22. The light emitted by the first light emission device 21 in the light emission range l₁ can be received by the human eye, and the light emitted by the second light emission device 22 in the light emission range l₂ can be received by the human eye. Assuming that the height of the first light-blocking structure 31 is the same as the height of the second light-blocking structure 32, the light S1′ emitted by the first light-emitting device 21 (the light shown by a dotted line in FIG. 5) can also be received by the human eye, at this time, the light emission range of the first light-emitting device 21 is l₁′, it can be seen that the light emission range l₁′ is greater than the light emission range l₁, which means that more light emitted by the first light-emitting device 21 can be received by the human eye. In the embodiments of the present disclosure, the thickness of the first light-blocking structure 31 is increased so that the height of the first light-blocking structure 31 is greater than the height of the second light-blocking structure 32, and the first light-blocking structure 31 blocks some light in the light emission range l₁′ toward the human eye, so that the light emission range of the first light-blocking structure 31 is reduced to the light emission range l₁. The first light-blocking structure 31 is used to reduce the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

In the embodiments shown in FIG. 5, the height h1 of the first light-blocking structure 31 is higher than the height h2 of the second light-blocking structure 32, and on the premise of satisfying the height relationship between the first light-blocking structure 31 and the second light-blocking structure 32, the size relationship between the thickness of the first light-blocking structure 31 and the thickness of the second light-blocking structure 32 may not be defined.

Each of FIG. 4 and FIG. 5 illustrates that the display panel is a tablet-type display panel, the first display region AA1 can be considered a central region of the display panel, and the second display region AA2 is an edge region adjacent to the non-display region NA. When front viewing the display panel, the viewing angle of the first display region AA1 is smaller than the viewing angle of the second display region AA2. In the embodiments of the present disclosure, a thickness d1 of the first light-blocking structure 31 is greater than a thickness d2 of the second light-blocking structure 32, or a height h1 of the first light-blocking structure 31 is set higher than a height h2 of the second light-blocking structure 32. The light-blocking ability of the first light-blocking structure 31 to the first light-emitting device 21 is greater than the light-blocking ability of the second light-blocking structure 32 to the second light-emitting device 22, the first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

The present disclosure further provides a curved display panel. FIG. 6 is a schematic diagram of a display panel according to another embodiment of the present disclosure. As shown in FIG. 6, the first display region AA1 is a flat plane region, and the second display region AA2 is a curved region. When a user views the display panel from the position of the first display region AA, the viewing angle of the first display region AA1 is α3, and the viewing angle of the second display region AA2 is α4, and the α3 is less than α4. In FIG. 6, if the thickness of the first light-blocking structure 31 is greater than the thickness of the second light-blocking structure 32. By increasing the thickness of the first light-blocking structure 31 to increase its light-blocking ability to the first light-emitting device 21, the first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

In another embodiment, the first display region AA1 is a flat plane region, the second display region AA2 is a curved region, the height of the first light-blocking structure 31 is set higher than the height of the second light-blocking structure 32, the first light-blocking structure 31 is used to reduce the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

In some embodiments, the first display region AA1 and the second display region AA2 can be flat plane regions or curved regions, which are not limited here. For the convenience of schematic illustration, the first display region AA1 and the second display region AA2 are both flat plane regions in the following embodiments.

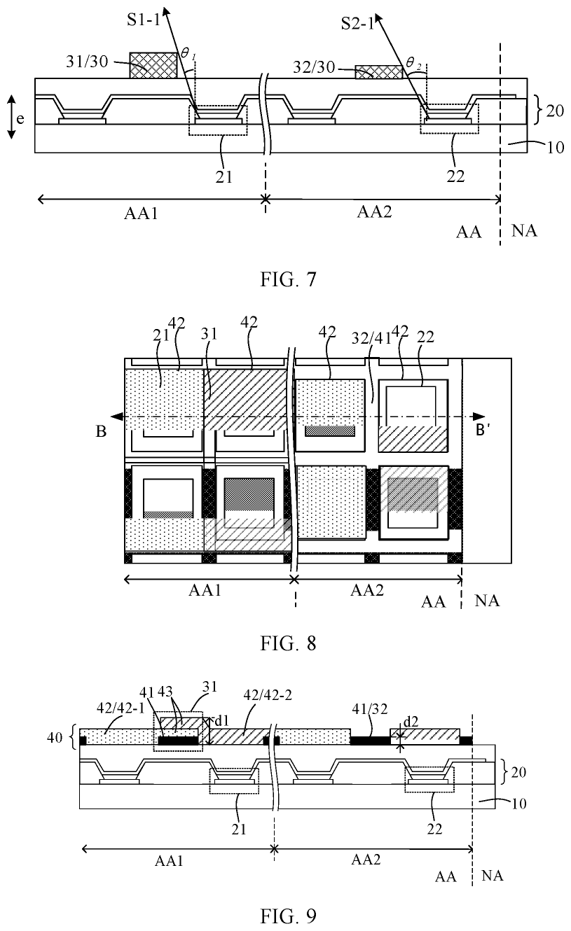

FIG. 7 is a schematic diagram of a display panel according to another embodiment of the present disclosure. In some embodiments, FIG. 7 only schematically shows that the thickness of the first light-blocking structure 31 is greater than the thickness of the second light-blocking structure 32. The first light-emitting device 21 and the second light-emitting device 22 each have a critical emergence angle. The critical emergence angle is a maximum angle formed between the light emitted by the edge of the light-emitting device that can finally exit the display panel and a direction of front viewing the light-emitting device. In the embodiments of FIG. 7, the direction of front viewing the light-emitting device is parallel to a direction e perpendicular to the plane of substrate 10. The first light-blocking structure 31 is adjacent to the first light-emitting device 21. The light emitted by one end of the first light-emitting device 21 adjacent to the first light-blocking structure 31 and not blocked by the first light-blocking structure 31 is light S1-1, and an angle formed between the light S1-1 and the direction of front viewing the first light-emitting device 21 is the critical emergence angle θ₁. Similarly, for the second light-emitting device 22, the light emitted by one end of the second light-emitting device 22 adjacent to the second light-blocking structure 32 and not blocked by the second light-blocking structure 32 is light S2-1, and an angle formed between the light S2-1 and the direction of front viewing the second light-emitting device 22 is the critical emergence angle θ₂, where θ₁<θ₂. The critical emergence angle can affect the amount of light emitted by the light-emitting device. Setting θ₁<θ₂ in the embodiments of the present disclosure is capable of reducing the amount of the light emitted by the first light-emitting device 21 so that the amount of the light emitted by the first light-emitting device 21 is less than the amount of the light emitted by the second light-emitting device 22, and the amount of light emitted by the first light-emitting device 21 that can emit toward human eyes can be reduced, so as to balance the brightness difference between the first display region AA1 and the second display region AA2 due to different viewing angles, and the difference in brightness received by the human eye when observing the two regions is reduced, thereby improving visually uneven brightness and the visual effect.

In some embodiments, the critical emergence angles of the first light-emitting device 21 and the second light-emitting device 22 can be adjusted by setting the thickness or height relationship between the first light-blocking structure 31 and the second light-blocking structure 32 to achieve that the critical emergence angle of the first light-emitting device 21 is smaller than the critical emergence angle of the second light-emitting device 22.

FIG. 8 is an enlarged view of the region Z shown in FIG. 2 according to another embodiment of the present disclosure, and FIG. 9 is a cross-sectional view at the position of line B-B′ shown in FIG. 8 according to an embodiment of the present disclosure. In some embodiments, referring to FIG. 8 and FIG. 9, the display panel includes a color filter layer 40 located on a side of light-emitting device layer 20 away from substrate 10. The color filter layer 40 includes a black matrix 41 and multiple color filter units 42. The black matrix 41 includes a hollow portion, and the arrangement of the color filter units 42 in FIG. 8 is for illustrative purposes only and is not meant to limit the present disclosure. As can be seen in FIG. 8, in a layer stacking direction of the display panel, the hollow portion of black matrix 41 overlaps with the light-emitting device. In the layer stacking direction of the display panel, the color filter unit 42 overlaps with the hollow portion of the black matrix 41, and the color filter unit 42 overlaps the light-emitting device. The black matrix 41 has a light-shielding property, and the color filter unit 42 has a filtering property. The color filter unit 42 includes at least a red color filter unit, a green color filter unit, and a blue color filter unit. The color filter unit 42 is capable of filtering out light different from its own color so that light of the same color as its own color is transmitted. When the ambient light emits toward the display panel, the red light component in the ambient light can penetrate the red color filter unit and then be reflected by the metal structure under the red color filter unit, and the reflected light is still red light, the red light emitted toward the adjacent green color filter unit or the blue color filter unit is confined inside the display panel and cannot exit, thereby reducing the reflected light emitted by the display panel. The filtering characteristic of color filter unit 42 can reduce the reflection of ambient light by the display panel, improving the display effect.

Referring to FIG. 8 and FIG. 9, the first light-blocking structure 31 includes a stacking structure consisting of the black matrix 41 and the color filter portion 43. The color filter portion 43 includes color filter unit 42, and the color filter portion 43 has a light-blocking ability. The second light-blocking structure 32 includes a black matrix 41. The second light-blocking structure 32 includes only the black matrix 41, and does not include the color filter portion 43. By providing the first light-blocking structure 31 to include the black matrix 41 and the color filter portion 43 that are stacked, the thickness of the first light-blocking structure 31 can be increased so that the thickness d1 of the first light-blocking structure 31 is greater than the thickness d2 of the second light-blocking structure 32. Therefore, the light-blocking ability of the first light-blocking structure 31 to the first light-emitting device 21 is increased, the first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect. In the embodiments of the present disclosure, the color filter layer 40 is used to reduce the reflection of ambient light by the display panel, improving the display effect. Meanwhile, the first light-blocking structure 31 is manufactured by using the black matrix 41 and the color filter unit 42 in the color filter layer 40, the second light-blocking structure 32 is manufactured by using the black matrix 41 in the color filter layer 40, no new processing process is added, and visually uneven brightness caused by different viewing angles can be improved.

As shown in FIG. 9, the color filter portion 43 includes a first stacking structure consisting of the color filter units 42 of at least two colors, so that the color filter portion 43 has a light-blocking ability. Alternatively, the edges of adjacent color filter units 42 with different colors overlap with each other to form the color filter portion 43. The color filter portion 43 in FIG. 9 includes a first color filter unit 42-1 and a second color filter unit 42-2 that are overlapped. The first color filter unit 42-1 and the second color filter unit 42-2 have different colors. The first color filter unit 42-1 and the second color filter unit 42-2 are any two of a red color filter unit, a green color filter unit, and a blue color filter unit.

The second light-blocking structure 32 includes a black matrix 41. In the embodiments of FIG. 9, the color filter unit 42 adjacent to the second light-blocking structure 32 within the second display region AA2 does not overlap with the second light-blocking structure 32.

In some embodiments, the first light-blocking structure 31 includes a stacking structure consisting of the black matrix 41 and the color filter portion 43. The color filter portion 43 is located on a side of the black matrix 41 away from substrate 10. The second light-blocking structure 32 includes the black matrix 41. The thickness of black matrix 41 in the first display region AA1 is smaller than the thickness of black matrix 41 in the second display region AA2. With such a configuration, by using the black matrix 41 and the color filter portion 43 that are stacked as the first light-blocking structure 31, the thickness of the first light-blocking structure 31 is increased, so that the light-blocking ability of the first light-blocking structure 31 is increased. Decreasing the thickness of black matrix 41 in the first display region AA can ensure that the thickness of the first light-blocking structure 31 is not significantly greater than the thickness of the second light-blocking structure 32, thus improving planarization of layers while having appropriate light-blocking thickness.

In other embodiments, the first light-blocking structure 31 includes a stacking structure consisting of a black matrix 41 and a color filter portion 43. The color filter portion 43 is located on a side of the black matrix 41 away from the substrate 10. The second light-blocking structure 32 includes the black matrix 41. The thickness of a portion of the color filter unit 40 overlapping with the black matrix 41 in the first display region AA1 is smaller than the thickness of a portion of the color filter unit 40 overlapping with the first light-emitting device 21. With such a configuration, by using the black matrix 41 and the color filter portion 43 that are stacked as the first light-blocking structure 31, the thickness of the first light-blocking structure 31 is increased, thereby increasing the light-blocking ability of the first light-blocking structure 31. Reducing the thickness of a portion of the color filter unit 40 overlapping with the black matrix 41 in the first display region AA can ensure that the thickness of the first light-blocking structure 31 is not much (i.e., not significantly) greater than the thickness of the second light-blocking structure 32, improving planarization of layers while having appropriate light-blocking thickness.

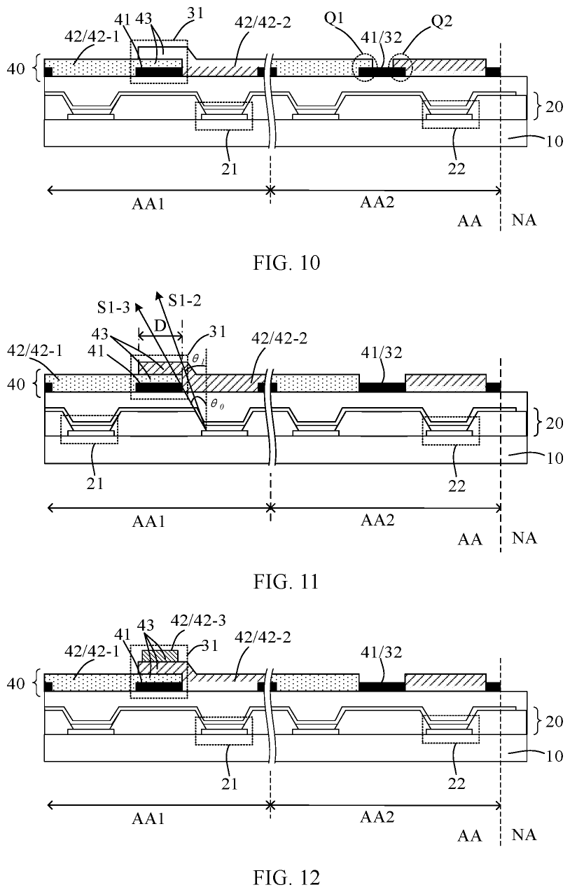

FIG. 10 is a schematic diagram of a display panel according to another embodiment of the present disclosure. In another embodiment, as shown in FIG. 10, the first light-blocking structure 31 includes a stacking structure consisting of a black matrix 41 and a color filter portion 43, the second light-blocking structure 32 includes a black matrix 41, and the color filter unit 42 overlaps with the second light-blocking structure 32 at a position of the second light-blocking structure 32. As illustrated by the region Q1 and the region Q2 in FIG. 10, in the same position of the second light-blocking structure 32, the second light-blocking structure 32 only overlaps with one color blocking unit 42, so that the color blocking unit 42 at the overlapping position of region Q1 and region Q2 cannot form the color filter portion, thereby not blocking light. The thickness of the second light-blocking structure 32 in the embodiments of FIG. 10 is the thickness of the black matrix 41.

In some embodiments, when the display panel is manufactured, the black matrix 41 is first manufactured, and the color filter unit 42 is manufactured after the manufacturing process of the black matrix 41, and the color filter unit 42 is located on a side of the black matrix 41 away from the substrate 10. In the embodiments of the present disclosure, the color filter portion 43 includes a color filter unit 42, as shown in FIG. 9, the color filter portion 43 is located on a side of black matrix 41 away from substrate 10, the color filter portion 43 consisting of the color filter unit 42 is stacked on the black matrix 41, the color filter portion 43 and black matrix 41 stacks to form the first light-blocking structure 32, so that the first light-blocking structure 32 has a larger thickness, and the light-blocking ability of the first light-blocking structure 31 to the first light-emitting device 21 is greater than the light-blocking ability of the second light-blocking structure 32 to the second light-emitting device 22, the first light-blocking structure 31 is used to reduce the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

In some embodiments, FIG. 11 is a schematic diagram of a display panel according to another embodiment of the present disclosure. As shown in FIG. 11, the light emitted by one end of the first light-emitting device 21 adjacent to the first light-blocking structure 31 and not blocked by the color filter portion 43 is light S1-2, an angle θ₁ is formed between the light S1-2 and the direction of front viewing the first light-emitting device 21, and the angle θ₁ is the critical emergence angle of the first light-emitting device 21, in other words, the color filter portion 43 corresponds to the critical emergence angle θ₁ of the first light-emitting device 21. The light emitted by one end of the first light-emitting device 21 adjacent to its adjacent first light-blocking structure 31 and not blocked by the black matrix 41 is light S1-3, and an angle θ₀ is formed between the light S1-3 and the direction of front viewing the first light-emitting device 21. The angle θ₀ is a first critical emergence angle of the first light-emitting device 21 (the first critical emergence angle is not the actual critical emergence angle), in other words, the black matrix 41 corresponds to the first critical emergence angle θ₀ of the first light-emitting device 21. The angles θ₁ and θ₀ satisfy θ₁<θ₀. In an embodiment, the color filter portion 43 is provided on the side of black matrix 41 away from the substrate 10, the color filter portion 43 and black matrix 41 are stacked so that the first light-blocking structure 31 has a larger thickness, the light emission of the first light-emitting device 21 can be blocked with the color filter portion 43, thereby defining the critical emergence angle θ₁ of the first light-emitting device 21 by using the color filter portion 43.

In addition, as shown in FIG. 11, the color filter portion 43 has a certain width D, the width D of the color filter portion 43 is the width of the first stack structure consisting of the color filter units 42 of at least two colors, and the width D is an overlapping width of the color filter units 42 stacked on each other in the cross-sectional view. The width D of the color filter portion 43 can affect the critical emergence angle θ₁ of the first light-emitting device 21. In some embodiments, the width D of the color filter portion 43 gradually decreases in a direction from the first display region AA1 to the second display region AA2, thereby achieving a gradual adjustment of the critical emergence angle size of the first light-emitting device 21. The light-blocking ability of the first light-blocking structure 31 to the first light-emitting device 21 gradually decreases in a direction from the first display region AA1 to the second display region AA2, thereby achieving a gradual change in the visual brightness from the first display region AA1 to the second display region AA2, and improving the visual effect.

In some embodiments, the color filter unit 42 with a largest distance from the black matrix 41 among the color filter units 42 of the color filter portion 43 is a red color filter unit or a blue color filter unit.

FIG. 12 is a schematic diagram of a display panel according to another embodiment of the present disclosure. As shown in FIG. 12, at least some color filter portions 43 in the display panel include a first color filter unit 42-1, a second color filter unit 42-2, and a third color filter unit 42-3 that are stacked sequentially. The third color filter unit 42-3 is a color filter unit with a largest distance from black matrix 41. In an embodiment, the third color filter unit 42-3 is a red color filter unit, one of the first color filter unit 42-1 and the second color filter unit 42-2 is a green color filter unit, and the other of the first color filter unit 42-1 and the second color filter unit 42-2 is a blue color filter unit. In another embodiment, the third color filter unit 42-3 is a blue color filter unit, one of the first color filter unit 42-1 and the second color filter unit 42-2 is a green color filter unit, and the other of the first color filter unit 42-1 and the second color filter unit 42-2 is a red color filter unit. In an embodiment, setting some color filter portions 43 to include the structure stacked by the color filter units of three colors can increase the thickness of the color filter portion 43, so that the thickness of the first light-blocking structure 31 is further increased, thereby improving the light-blocking ability of the first light-blocking structure 31. In addition, if the color filter portion 43 is set to include the structure stacked by color filter units of three colors, the light-blocking ability of the color filter portion 43 is stronger, which is beneficial to reduce the reflectivity of the display panel.

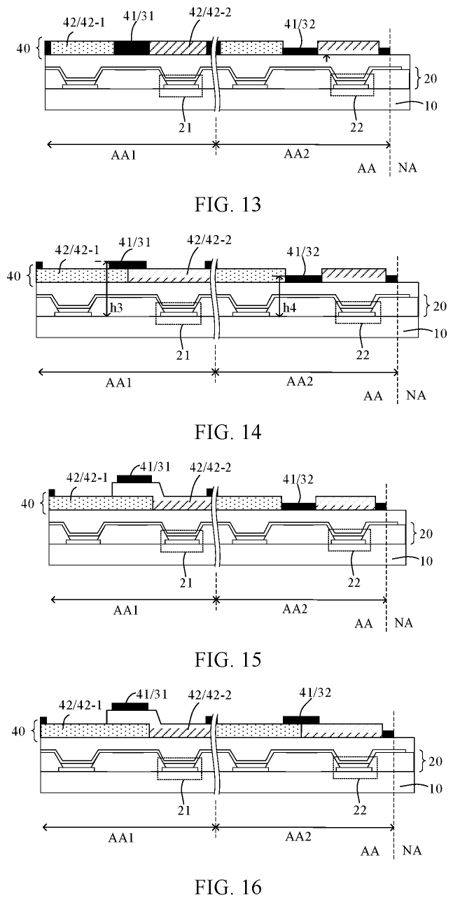

FIG. 13 is a schematic diagram of a display panel according to another embodiment of the present disclosure. In another embodiment, as shown in FIG. 13, the color filter layer 40 is located on a side of light-emitting device layer 20 away from substrate 10. The color filter layer 40 includes a black matrix 41 and multiple color filter units 42. The color filter unit 42 includes color filter units with at least three different colors. Only a first color filter unit 42-1 and a second color filter unit 42-2 with different colors are illustrated in FIG. 13. The black matrix 41 includes a hollow portion which overlaps with the light-emitting device in the layer stacking direction of the display panel. In the layer stacking direction of the display panel, the color filter unit 42 overlaps with the hollow portion of black matrix 41, and at least a portion of the color filter unit 42 overlaps with the light-emitting device. The black matrix 41 has a shading property, and the color filter unit 42 has the filtering property. The filtering characteristic of color filter unit 42 can reduce the reflection of ambient light by display panel, improving the display effect. Each of the first light-blocking structure 31 and the second light-blocking structure 32 includes a black matrix 41. A thickness of black matrix 41 in the first light-blocking structure 31 is greater than a thickness of black matrix 41 in the second light-blocking structure 32. In an embodiment, a thickness of the black matrix 41 in the first display region AA1 is greater than a thickness of black matrix 41 in the second display region AA2, and the black matrix 41 is reused into a light-blocking structure. The greater the thickness of black matrix 41, the stronger its light-blocking ability, so that the light-blocking ability of the first light-blocking structure 31 to the first light-emitting device 21 is greater than the light-blocking ability of the second light-blocking structure 32 to the second light-emitting device 22. The first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

FIG. 14 is a schematic diagram of a display panel according to another embodiment of the present disclosure. In another embodiment, as shown in FIG. 14, the color filter layer 40 is located on a side of light-emitting device layer 20 away from substrate 10. The color filter layer 40 includes a black matrix 41 and a color filter unit 42. The black matrix 41 includes a hollow portion which overlaps with the light-emitting device in a layer stacking direction of the display panel. In the layer stacking direction of the display panel, the color filter unit 42 overlaps with the hollow portion of black matrix 41, and at least a portion of the color filter unit 42 overlaps with the light-emitting device. The black matrix 41 has a shading property, and the color filter unit 42 has the filtering property. The filtering characteristic of color filter unit 42 can reduce the reflection of ambient light by display panel, improving the display effect. Each of the first light-blocking structure 31 and the second light-blocking structure 32 includes a black matrix 41. A height of black matrix 41 in the first light-blocking structure 31 is higher than a height of black matrix 41 in the second light-blocking structure 32. The height of the black matrix 41 is compared by a same reference plane in the layer of the display panel. As shown in FIG. 14, a vertical distance between the surface of the black matrix 41 located on a side away from the substrate 10 in the first light-blocking structure 31 and the substrate 10 is a height h3 of the black matrix 41, and a vertical distance between the surface of the black matrix 41 located on a side away from substrate 10 in the second light-blocking structure 32 and the substrate 10 is a height h4 of the black matrix 41. The height h3 is greater than the height h4. The height of the black matrix 41 in the first display region AA1 is greater than the height of black matrix 41 in the second display region AA2, and the black matrix 41 is reused into a light-blocking structure. The greater the height of black matrix 41, the stronger its light-blocking ability, so that the light-blocking ability of the first light-blocking structure 31 to the first light-emitting device 21 is increased. The first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

As shown in FIG. 14, the layer of color filter unit 42 is located on a side of the layer of the black matrix 41 adjacent to the substrate 10, and the first light-blocking structure 31 overlaps with the color filter unit 42. There is a gap between two color filter units 42 adjacent to the second light-blocking structure 32. The second light-blocking structure 32 is located in the gap. When the display panel provided by the embodiments is manufactured, the color filter unit 42 is first manufactured, and then the black matrix 41 is manufactured after the manufacturing process of color filter unit 42. Each of the first light-blocking structure 31 and the second light-blocking structure 32 is set to be include the black matrix 41, and the first light-blocking structure 31 overlaps with the color filter unit 42, so that the black matrix 41 can be lifted by the color filter unit 42, thereby achieving the height of the first light-blocking structure 31 to be higher than the height of the second light-blocking structure 32. Therefore, the light-blocking ability of the first light-blocking structure 31 to the first light-emitting device 21 is greater than the light-blocking ability of the second light-blocking structure 32 to the second light-emitting device 22.

The color filter unit 42 includes color filter units of at least three colors. A first color filter unit 42-1 and a second color filter unit 42-2 with different colors are schematically illustrated in FIG. 14. The edge of the first color filter unit 42-1 and the edge of second color filter unit 42-2 are in contact with each other, and the black matrix 41 is stacked above the first color filter unit 42-1 and the second color filter unit 42-2 that are in contact with each other to lift the black matrix 41 high, thereby using the black matrix 41 as the first light-blocking structure 31.

In another embodiment, at least two color filter units 42 stacked are provided under the first light-blocking structure 31. FIG. 15 is a schematic diagram of a display panel according to another embodiment of the present disclosure. As shown in FIG. 15, at the position of the first light-blocking structure 31, the edge of the first color filter unit 42-1 overlaps with the edge of the second color block unit 42-2. The black matrix 41 above the first color filter unit 42-1 and the second color filter unit 42-2 that overlaps with each other is reused as the first light-blocking structure 31. Such a configuration can make the height of the first light-blocking structure 31 be higher, so that the light-blocking ability of the first light-blocking structure 31 to the first light-emitting device 21 can be increased.

In another embodiment, FIG. 16 is a schematic diagram of a display panel according to another embodiment of the present disclosure. As shown in FIG. 16, the black matrix 41 is located on a side of the layer of the color filter unit 42 away from the substrate 10. The first light-blocking structure 31 and the second light-blocking structure 32 each include a black matrix 41. At the position of the black matrix 41 of the first light-blocking structure 31, the edge of the first color filter unit 42-1 and the edge of the second color filter unit 42-2 overlap with each other. At the position of the black matrix 42 of the second light-blocking structure 32, the edge of the first color filter unit 42-1 and the edge of the second color filter unit 42-2 are in contact with each other. With such a configuration, the height of the first light-blocking structure 31 is higher than the height of the second light-blocking structure 32, so that the light-blocking ability of the first light-blocking structure 31 to the first light-emitting device 21 is increased.

In some embodiments, the black matrix 41 is located on a side of the color filter unit 40 away from substrate 10. The first light-blocking structure 31 includes a black matrix 41. The black matrix 41 is lifted by the color filter unit 40 within the first display region AA1 to be used as the first light-blocking structure 31. In an embodiment, a thickness of the portion of the color filter unit 40 overlapping with the black matrix 41 within the first display region AA1 is less than a thickness of the portion of the color filter unit 40 overlapping with the first light-emitting device 21. With such a configuration, the first light-blocking structure 31 is lifted by using the color filter unit 40, and the height of the first light-blocking structure 31 is increased, thereby increasing the light-blocking ability of the first light-blocking structure 31. Reducing the thickness of the portion of the color filter unit 40 overlapping with the black matrix 41 within the first display region AA can ensure that the height of the first light-blocking structure 31 is not much higher than the height of the second light-blocking structure 32, thereby improving planarization of layers.

In another embodiment, the thickness of the black matrix 41 in the first display region AA1 is set to be smaller than the thickness of black matrix 41 in the second display region AA2. With such a configuration, the first light-blocking structure 31 is lifted by using the color filter unit 40, the height of the first light-blocking structure 31 is increased, thereby increasing the light-blocking ability of the first light-blocking structure 31. Reducing the thickness of black matrix 41 in the first display region AA can ensure that the height of the first light-blocking structure 31 is not much higher than the height of the second light-blocking structure 32, thereby improving planarization of layers.

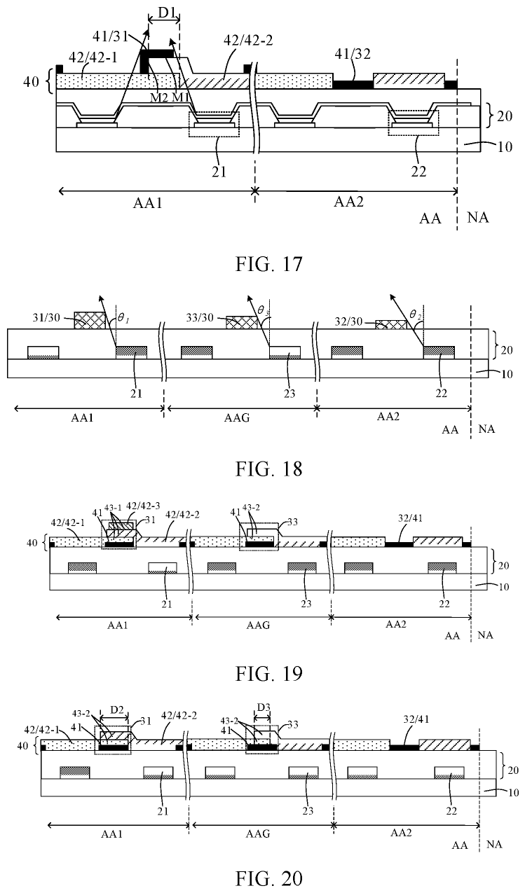

FIG. 17 is a schematic diagram of a display panel according to another embodiment of the present disclosure. In another embodiment, as shown in FIG. 17, in the region where the first light-blocking structure 31 is located, the color filter unit 42 has a first surface M1 and a first side surface M2. The first surface M1 is a surface located at a side of the color filter unit 42 of the substrate 10. The first side surface M2 is connected to the first surface M1, and an angle is formed between the first surface M1 and the first side surface M2. The first surface M1 and the first side surface M2 are not located at a same horizontal plane. The first light-blocking structure 31 covers at least a portion of the first surface M1 and at least a portion of the first side surface M2. When the display panel provided by the embodiments is manufactured, the color filter unit 42 is first manufactured, and then the black matrix 41 is manufactured after the manufacturing process of the color filter unit 42. In the first display region AA1, the edges of adjacent color filter units 42 overlap with each other, the black matrix 41 is manufactured over the color filter units 42 overlapped with each other, the black matrix 41 can be lifted so that the black matrix 41 lifted is used as the first light-blocking structure 31. The black matrix 41 covering on the first surface M1 plays a role of adjusting the critical emergence angle of the first light-emitting device 21 adjacent thereto, thereby reducing the amount of light emitted by the first light-emitting device 21 by using the first light-blocking structure 31, and balancing the brightness difference between the first display region AA1 and the second display region AA2 due to different viewing angles.

In the embodiments of FIG. 17, a structure formed by overlapping the edges of adjacent color filter units 42 can be referred to as a pad layer, the function of the pad layer is to lift the black matrix 41 above it, and the pad layer has a certain width D1. The width D1 of the pad layer can affect the width of the portion of the black matrix 41 covering on the first surface M1, so the width of black matrix 41 covering on the first surface M1 can be adjusted by adjusting the width D1 of the pad layer, thereby adjusting the light-blocking ability of the first light-blocking structure 31.

FIG. 18 is a schematic diagram of a display panel according to another embodiment of the present disclosure. In some embodiments, as shown in FIG. 18, the display region AA further includes a transition display region AAG located between the first display region AA1 and the second display region AA2. The light-emitting device in the display layer 20 further includes a third light-emitting device 23 located in the transition display region AAG. The third light-emitting device 23 is only named according to the position on which it is located. The third light-emitting device 23 includes a red light-emitting device, a green light-emitting device, and a blue light-emitting device. The light-blocking structure 30 further includes a third light-blocking structure 33 adjacent to the third light-emitting device 23. The third light-blocking structure 33 is configured to block light emitted from the third light-emitting device 23. In an embodiment, the transition display region AAG is provided between the first display region AA1 and the second display region AA2, and the third light-blocking structure 33 is provided in the transition display region AAG to adjust the light emission of the third light-emitting device 23. The thickness of the first light-blocking structure 31 is set to be greater than the thickness of the third light-blocking structure 33, and the thickness of the third light-blocking structure 33 is set to be greater than the thickness of the second light-blocking structure 32. Alternatively, the height of the first light-blocking structure 31 is set to be higher than the height of the third light-blocking structure 33, and the height of the third light-blocking structure 33 is set to be higher than the height of the second light-blocking structure 32. Therefore, the light-blocking ability of the first light-blocking structure 31 is greater than the light-blocking ability of the third light-blocking structure 33, and the light-blocking ability of the third light-blocking structure 33 is greater than the light-blocking ability of the second light-blocking structure 32, so that the reduction degree of the light emission amount of the first light-emitting device 21 is greater than the reduction degree of the light emission amount of the third light-emitting device 23, and the reduction degree of the light emission amount of the third light-emitting device 23 is greater than the reduction degree of the light emission amount of the second light-emitting device. In other words, from the first display region AA1 to the transition display region AAG and then to the second display region AA2, the light-blocking degree of light-emitting devices by using the light-blocking structure 30 gradually decreases, so that the brightness difference caused by different viewing angles is reduced when viewing different display regions. Therefore, the human eye can identify a gradual transition of brightness from the first display region AA1 to the transition display region AAG and then to the second display region AA2 when viewing the display panel, thereby improving the visually uneven brightness and the visual effect.

In some embodiments, as shown in FIG. 18, the critical emergence angle of the first light-emitting device 21 is θ₁, the critical emergence angle of the second light-emitting device 22 is θ₂, the critical emergence angle of the third light-emitting device 23 is θ₃, and the definition of the critical emergence angle can be found in the description of the related embodiments described above, which is not repeated herein. The angles θ₁, θ₂ and θ₃ satisfy: θ₁<θ₃<θ₂. Such a configuration can achieve a gradual increase in the light emission amount of the first light-emitting device 21, the third light-emitting device 23 and the second light-emitting device 22, it is possible to balance brightness differences between different display regions due to different viewing angles so that the human eye can identify a gradual transition of brightness from the first display region AA1 to the transition display region AAG and then to the second display region AA2 when viewing the display panel, thereby improving the visually uneven brightness and the visual effect.

FIG. 19 is a schematic diagram of a display panel according to another embodiment of the present disclosure. In some embodiments, as shown in FIG. 19, the display panel includes a color filter layer 40 located on a side of light-emitting device layer 20 away from substrate 10. The color filter layer 40 includes a black matrix 41 and multiple color filter units 42. The color filter unit 42 includes a first color filter unit 42-1, a second color filter unit 42-2, and a third color filter unit 42-3 that have different colors from one another. The layer of the color filter unit 42 is located on a side of the layer of black matrix 41 away from the substrate 10. The color filter unit 42 is manufactured after the manufacturing process of the black matrix 41. The first light-blocking structure 31 includes a black matrix 41 and a first color filter portion 43-1. The first color filter portion 43-1 is a stacking structure consisting of color filter units 42 of three colors. The third light-blocking structure 33 includes a black matrix 41 and the second color filter portion 43-2. The second color filter portion 43-2 is a stacking structure consisting of color filter units 42 of two colors. The second light-blocking structure 32 includes the black matrix 41. Such a configuration can achieve that the thickness of the first light-blocking structure 31 is greater than the thickness of the third light-blocking structure 33, and the thickness of the third light-blocking structure 33 is greater than the thickness of the second light-blocking structure 32. If the thicknesses of the light-blocking structures 30 are different, the light-blocking abilities of various light-blocking structures 30 are different. This embodiment can achieve that the light-blocking ability of the first light-blocking structure 31 is greater than the light-blocking ability of the third light-blocking structure 33, and the light-blocking ability of the third light-blocking structure 33 is greater than the light-blocking ability of the second light-blocking structure 32, so that the reduction degree of the light emission amount of the first light-emitting device 21 is greater than the reduction degree of the light emission amount of the third light-emitting device 23, and the reduction degree of the light emission amount of the third light-emitting device 23 is greater than the reduction degree of the light emission amount of the second light-emitting device. From the first display region AA1 to the transition display region AAG and then to the second display region AA2, the light-blocking degree of light-emitting devices by using the light-blocking structure 30 gradually decreases, so that the brightness difference caused by different viewing angles is reduced when viewing different display regions. Therefore, the human eye can identify a gradual transition of brightness from the first display region AA1 to the transition display region AAG and then to the second display region AA2 when viewing the display panel, thereby improving the visually uneven brightness and the visual effect.

FIG. 20 is a schematic diagram of a display panel according to another embodiment of the present disclosure. In some embodiments, as shown in FIG. 20, each of the first light-blocking structure 31 and the third light-blocking structure 33 includes a black matrix 41 and a stacking structure consisting of color filter units 42 of at least two colors. FIG. 20 schematically shows that each of the first light-blocking structure 31 and the third light-blocking structure 33 includes the second color filter portion 43-2 consisting of the overlapped color filter unit 42 of two colors. The second light-blocking structure 32 includes the black matrix 41. A width of the overlapping region of various color filter units 42 in the first light-blocking structure 31 is D2, and a width of the overlapping region of various color filter units 42 in the third light-blocking structure 33 is D3, where D2 is greater than D3. The width of the overlapping region of color filter units 42 affects the distance from the light-emitting device to the overlapping region in a horizontal direction. In a plane region of the display panel, the horizontal direction is a direction parallel to the plane of the substrate 10. In the curved region of the display panel, the horizontal direction can be considered to be a direction parallel to the plane in which the light-emitting device is located.

In the embodiments of the present disclosure, the color filter portion is set to be stacked on the black matrix 41, and the color filter portion is formed by overlapping color filter units 42 of at least two colors. The width of the color filter portion is a width of the overlapping region of the color filter units in the light-blocking structure. The color filter portion can play a role of light-blocking. Since the color filter portion is located on a side of the black matrix 41 away from the substrate 10, in the light-blocking structure 30 including the color filter portion and the black matrix, the width of the color filter portion has a great influence on the light-blocking ability of the light-blocking structure 30. When the thicknesses of the color filter portions are substantially the same, the light-blocking ability of the light-blocking structure can be adjusted by adjusting the width of the color filter portion. In the embodiments of the present disclosure, the first light-blocking structure 31 and the third light-blocking structure 33 each includes the stacking structure consisting of the black matrix 41 and color filter units 42 of at least two colors, so that the thicknesses of the first light-blocking structures 31 and the third light-blocking structures 33 are greater than the thickness of the second light-blocking structures 32. When the difference between the thickness of the first light-blocking structure 31 and the thickness of the third light-blocking structures 33 is not large, the width of the overlapping region of various color filter units 42 in the first light-blocking structure 31 is set to be greater than the width of the overlapping region of various color filter units 42 in the third light-blocking structures 33, so that the light-blocking ability of the first light-blocking structures 31 is greater than the light-blocking ability of the third light-blocking structures 33. In an embodiment, the light-blocking ability of the first light-blocking structure 31 is greater than the light-blocking ability of the third light-blocking structure 33, and the light-blocking ability of the third light-blocking structure 33 is greater than the light-blocking ability of the second light-blocking structure 32. Therefore, from the first display region AA1 to the transition display region AAG to the second display region AA2, the light-blocking structure 30 is utilized to gradually decrease the light-blocking degree of the light-emitting device, the brightness difference due to the different viewing angles when viewing different display regions is reduced, so that the human eye can identify a gradual transition from the first display region AA1 to the transition display region AAG and then to the second display region AA2 when viewing the display panel.

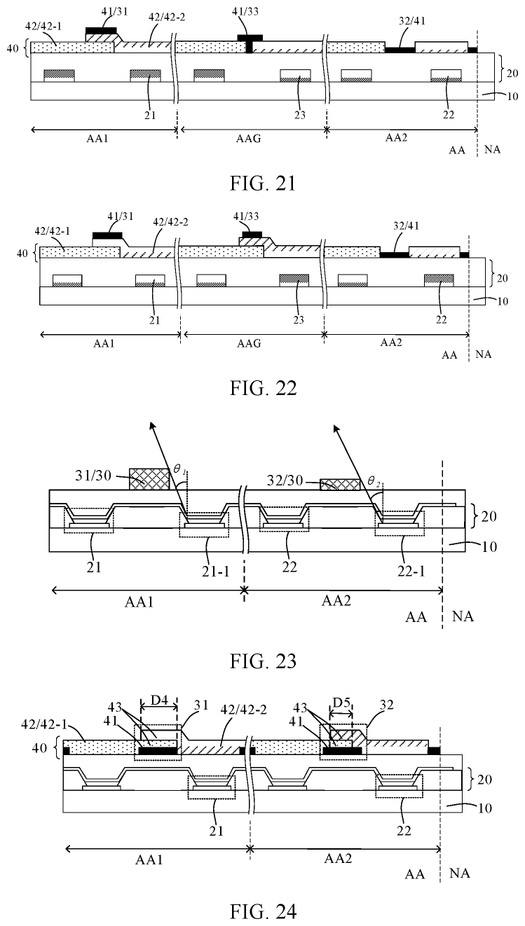

FIG. 21 is a schematic diagram of a display panel according to another embodiment of the present disclosure. In some embodiments, as shown in FIG. 21, the layer of color filter unit 42 is provided on a side of the layer of the black matrix adjacent to the substrate 10. The color filter unit 42 includes color filter units with at least three different colors. FIG. 21 only shows the first color filter unit 42-1 and the second color filter unit 42-2 of different colors. When the display panel is manufactured, the black matrix 41 is manufactured after the manufacturing process of color filter unit 42. The light-blocking structure 30 includes a black matrix 41. The first light-blocking structure 31 overlaps with the color filter unit 42. There is a gap between the color filter units 42 adjacent to the second light-blocking structure 32. The second light-blocking structure 32 is located in the gap. There is a gap between the color filter units 42 adjacent to the third light-blocking structure 33. The third light-blocking structure 33 includes a portion located in the gap and a portion covering the color filter unit 42. With such a configuration, the height of the first light-blocking structure 31 is higher than the height of the third light-blocking structure 33, and the height of the third light-blocking structure 33 is higher than the height of the second light-blocking structure 32. The light-blocking abilities of various light-blocking structures are adjusted by providing the light-blocking structures having different heights, so that the light-blocking ability of the first light-blocking structure 31 is greater than the light-blocking ability of the third light-blocking structure 33, and the light-blocking ability of the third light-blocking structure 33 is greater than the light-blocking ability of the second light-blocking structure 32. Therefore, from the first display region AA1 to the transition display region AAG to the second display region AA2, the light-blocking structure 30 is utilized to gradually decrease the light-blocking degree of the light-emitting device, the brightness difference due to the different viewing angles when viewing different display regions is reduced, so that the human eye can identify a gradual transition from the first display region AA1 to the transition display region AAG and then to the second display region AA2 when viewing the display panel.

In some embodiments, FIG. 22 is a schematic diagram of a display panel according to another embodiment of the present disclosure. As shown in FIG. 22, the layer of color filter unit 42 is provided on a side of the layer of the black matrix adjacent to substrate 10. The light-blocking structure 30 includes a black matrix. Each of the first light-blocking structure 31 and the third light-blocking structure 33 overlaps with the color filter unit 42. The width of the first light-blocking structure 31 is greater than the width of the third light-blocking structure 33. That is, the width of black matrix 41 in the first light-blocking structure 31 is greater than the width of black matrix 41 in the third light-blocking structure 33. In the embodiments of the present disclosure, the first light-blocking structure 31 and the third light-blocking structure 33 has a small difference in height, or has a substantially same height, so that the light-blocking ability of the first light-blocking structure 31 is greater than the light-blocking ability of the third light-blocking structure 33 by providing different widths of the first light-blocking structure 31 and the third light-blocking structure 33.

FIG. 23 is a schematic diagram of a display panel according to another embodiment of the present disclosure. In some embodiments, as shown in FIG. 23, the first light-emitting device 21 includes a first color first light-emitting device 21-1, and the second light-emitting device 22 includes a first color second light-emitting device 22-1. The light-emitting color of the first color first light-emitting device 21-1 is the same as the light-emitting color of the first color second light-emitting device 22-1. A critical emergence angle of the first color first light-emitting device 21-1 is θ₁, and a critical emergence angle of the first color second light-emitting device 22-1 is θ₂. That is, for the light-emitting devices of the same color, the critical emergence angle of light-emitting device in the first display region AA1 is smaller than the critical emergence angle of light-emitting device in the second display region AA. The light-emitting colors of the first color first light-emitting device 21-1 and the first color second light-emitting device 22-1 are any one of red, green, and blue.

According to the same inventive concept, the present disclosure further provides another display panel. FIG. 24 is a schematic diagram of a display panel according to another embodiment of the present disclosure. As shown in FIG. 24, the display panel includes a display region AA and a non-display region NA. The display region AA includes a first display region AA1 and a second display region AA2. The second display region AA2 is located between the first display region AA1 and the non-display region NA. The display panel includes a substrate 10, a light-emitting device layer 20, and a light-blocking structure 30.

The light-emitting device layer 20 is located on a side of substrate 10. The light-emitting device layer 20 includes multiple light-emitting devices. The light-emitting device includes a first light-emitting device 21 and a second light-emitting device 22. The first light-emitting device 21 is located in the first display region AA1, and the second light-emitting device 22 is located in the second display region AA2.

A light-blocking structure 30 is located on a side of light-emitting device layer 20 away from substrate 10. The light-blocking structure 30 includes a first light-blocking structure 31 and a second light-blocking structure 32. The first light-blocking structure 31 is provided adjacent to the first light-emitting device 21. The second light-blocking structure 32 is provided adjacent to the second light-emitting device 22.

The color filter layer 40 is located on a side of light-emitting device layer 20 away from substrate 10. The color filter layer 40 includes a black matrix 41 and multiple color filter units 42. The layer on which the color filter unit 42 is located is located on a side of black matrix 41 away from substrate 10. The color filter unit 42 includes color filter units of at least three different colors. Only a first color filter unit 42-1 and a second color filter unit 42-2 of different colors are illustrated in FIG. 21.

The light-blocking structure 30 includes a black matrix 41 and a color filter portion 43. The color filter portion 43 includes a stacking structure consisting of color filter units 42 of at least two colors. A width of an overlapping region of various color blocking units 42 of the color filter portion 43 is the width of the color filter portion 43. FIG. 24 shows that the edge of the first color filter unit 42-1 overlaps with the edge of the second color filter unit 42-2 to form the color filter portion 43. The width D4 of the color filter portion 43 in the first light-blocking structure 31 is greater than the width D5 of the color filter portion 43 in the second light-blocking structure 32.

In an embodiment, the color filter portion 43 is stacked on the black matrix 41, and the color filter portion 43 formed by overlapping the color filter units 42 of at least two colors. The color filter portion 43 can have a light-blocking effect. Since the color filter portion 43 is located on a side of black matrix 41 away from substrate 10, in the light-blocking structure 30 including the color filter portion 43 and black matrix 41, the width of the color filter portion 43 can greatly affect the light-blocking ability of the light-blocking structure 30. The light-blocking ability of the light-blocking structure can be adjusted by adjusting the width of the color filter portion 43 when the thicknesses of the color filter portions 43 are substantially the same. In an embodiment, the first light-blocking structure 31 and the second light-blocking structure 32 each include a stacking structure consisting of the black matrix 41 and color filter units 42 of at least two colors, at this time, the width of the color filter portion 43 in the first light-blocking structure 31 is set greater than the width of the color filter portion 43 in the second light-blocking structure 32, so that the light-blocking ability of the first light-blocking structure 31 is greater than the light-blocking ability of the second light-blocking structure 32. The first light-blocking structure 31 reduces the amount of light emitted by the first light-emitting device 21 that can emit toward human eyes, so as to balance the brightness difference between the first display region AA1 and the second display region AA2 due to different viewing angles, and the difference in brightness received by the human eye when observing the two regions is reduced, thereby improving visually uneven brightness and the visual effect.

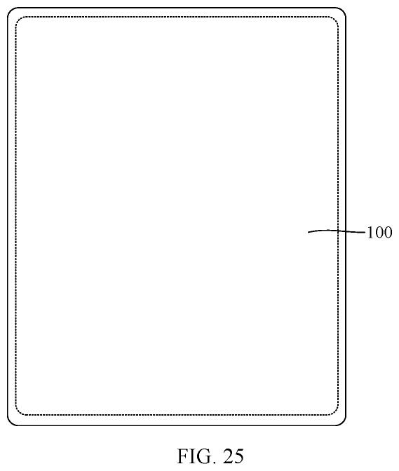

According to the same inventive concept, the present disclosure provides a display apparatus, and FIG. 25 is a schematic diagram of a display apparatus according to an embodiment of the present disclosure, and as shown in FIG. 25, the display apparatus includes a display panel 100 provided by any above embodiments. The structure of the display panel has been described in the above embodiments, and will not be repeated here. For example, the display apparatus provided by the present disclosure can be a mobile phone, a tablet computer, a laptop computer, a television, and the like.

The above are merely preferred embodiments of the present disclosure, which, as mentioned above, are not configured to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various obvious modifications, readjustments, and substitutions without departing from the scope of the present disclosure.

What is claimed is:

1. A display panel, comprising:
a display region and a non-display region, wherein the display region comprises a first display region and a second display region, and the second display region is located between the first display region and the non-display region;
a substrate;
a light-emitting device layer located on a side of the substrate, wherein the light-emitting device layer comprises light-emitting devices, the light-emitting devices comprise a first light-emitting device and a second light-emitting device, the first light-emitting device is located in the first display region, and the second light-emitting device is located in the second display region; and
light-blocking structures located on a side of the light-emitting device layer away from the substrate, wherein the light-blocking structures comprise a first light-blocking structure and a second light-blocking structure, the first light-blocking structure is provided adjacent to the first light-emitting device, and the second light-blocking structure is provided adjacent to the second light-emitting device;
wherein a thickness of the first light-blocking structure is greater than a thickness of the second light-blocking structure, or a height of the first light-blocking structure is higher than a height of the second light-blocking structure.

2. The display panel according to claim 1, wherein
a critical emergence angle θ₁ of the first light-emitting device and a critical emergence angle θ₂ of the second light-emitting device satisfy: θ₁<θ₂.

3. The display panel according to claim 1, further comprising:
a color filter layer located on the side of the light-emitting device layer away from the substrate, wherein
the color filter layer comprises a black matrix and color filter units;
the first light-blocking structure comprises a stacking structure consisting of the black matrix and a color filter portion, and the color filter portion comprises the color filter units; and
the second light-blocking structure comprises the black matrix.

4. The display panel according to claim 3, wherein
the color filter portion comprises a first stacking structure consisting of the color filter units of at least two colors.

5. The display panel according to claim 4, wherein
the color filter portion is located on a side of the black matrix away from the substrate.

6. The display panel according to claim 5, wherein
in the first light-blocking structure, the color filter portion corresponds to a critical emergence angle θ₁ of the first light-emitting device, and the black matrix corresponds to a first critical emergence angle θ₀ of the first light-emitting device, which satisfy: θ₁<θ₀.

7. The display panel according to claim 5, wherein
a color filter unit with a largest distance from the black matrix among the color filter units of the color filter portion is a red color filter unit or a blue color filter unit.

8. The display panel according to claim 1, further comprising:
a color filter layer located on the side of the light-emitting device layer away from the substrate, wherein
the color filter layer comprises a black matrix and color filter units;
the light-blocking structure comprises the black matrix; and
a thickness of the black matrix in the first light-blocking structure is greater than a thickness of the black matrix in the second light-blocking structure.

9. The display panel according to claim 1, further comprising:
a color filter layer located on the side of the light-emitting device layer away from the substrate, wherein
the color filter layer comprises a black matrix and color filter units;
the light-blocking structure comprises the black matrix; and
a height of the black matrix in the first light-blocking structure is greater than a height of the black matrix in the second light-blocking structure.

10. The display panel according to claim 9, wherein
a layer of the color filter units is located on a side of a layer of the black matrix adjacent to the substrate, and the first light-blocking structure overlaps with the color filter units; and
a gap is formed between two color filter units that are adjacent to the second light-blocking structure, and the second light-blocking structure is located in the gap.

11. The display panel according to claim 10, wherein
in a region where the first light-blocking structure is located, a color filter unit of the color filter units has a first surface and a first side surface, the first surface is a surface at a side of the color filter unit away from the substrate, the first side surface is connected to the first surface, and the first side surface and the first surface jointly form an angle; and
the first light-blocking structure covers at least a portion of the first surface and at least a portion of the first side surface.

12. The display panel according to claim 1, wherein
the display region further comprises a transition display region located between the first display region and the second display region;
the light-emitting devices further comprise a third light-emitting device located in the transition display region;
the light-blocking structures further comprise a third light-blocking structure adjacent to the third light-emitting device; and
the display panel further comprises a color filter layer located on the side of the light-emitting device layer away from the substrate, and the color filter layer comprises a black matrix and color filter units.

13. The display panel according to claim 12, wherein
the first light-blocking structure comprises a stacking structure consisting of the black matrix and the color filter units of three colors;
the third light-blocking structure comprises a stacking structure consisting of the black matrix and the color filter units of two colors; and
the second light-blocking structure comprises the black matrix.

14. The display panel according to claim 12, wherein
the first light-blocking structure and the third light-blocking structure each comprises a stacking structure consisting of the black matrix and color filter units of at least two colors;
the second light-blocking structure comprises the black matrix; and
a width of an overlapping region of each of the color filter units in the first light-blocking structure is greater than a width of an overlapping region of each of the color filter units in the third light-blocking structure.

15. The display panel according to claim 12, wherein
a layer of the color filter units is located on a side of a layer of the black matrix adjacent to the substrate;
the light-blocking structure comprises the black matrix;
the first light-blocking structure overlaps with a stacking structure formed by at least two color filter units;
a gap is formed between two color filter units adjacent to the second light-blocking structure, and the second light-blocking structure is located in the gap; and
a gap is formed between two color filter units adjacent to the third light-blocking structure, and the third light-blocking structure comprises a portion located in the gap and a portion covering the color filter unit.

16. The display panel according to claim 12, wherein
a layer of the color filter unit is located on a side of a layer of the black matrix adjacent to the substrate;
the light-blocking structure comprises the black matrix;
the first light-blocking structure and the third light-blocking structure each overlap with the color filter unit; and
a width of the first light-blocking structure is greater than a width of the third light-blocking structure.

17. The display panel according to claim 1, wherein
the light-emitting device layer further comprises a pixel definition layer, the pixel definition layer provides openings in which the light-emitting devices are located, and the light-blocking structure overlaps with the pixel definition layer.

18. The display panel according to claim 2, wherein
the first light-emitting device comprises a first color first light-emitting device; the second light-emitting device comprises a first color second light-emitting device; the light-emitting color of the first color first light-emitting device and the light-emitting color of the first color second light-emitting device are the same.

19. A display panel, comprising:
a display region and a non-display region, wherein the display region comprises a first display region and a second display region, and the second display region is located between the first display region and the non-display region;
a substrate;
a light-emitting device layer located on a side of the substrate, wherein the light-emitting device layer comprises light-emitting devices, the light-emitting devices comprise a first light-emitting device and a second light-emitting device, the first light-emitting device is located in the first display region, and the second light-emitting device is located in the second display region;
light-blocking structures located on a side of the light-emitting device layer away from the substrate, wherein the light-blocking structures comprise a first light-blocking structure and a second light-blocking structure, the first light-blocking structure is provided adjacent to the first light-emitting device, and the second light-blocking structure is provided adjacent to the second light-emitting device; and
a color filter layer located on the side of the light-emitting device layer away from the substrate, the color filter layer comprising a black matrix and color filter units;
wherein the light-blocking structure comprises a stacking structure consisting of the black matrix and the color filter units of at least two colors; and
a width of an overlapping region of each of the color filter units in the first light-blocking structure is greater than a width of an overlapping region of each of the color filter units in the second light-blocking structure.

20. A display apparatus, comprising a display panel, wherein the display panel comprises:
a display region and a non-display region, wherein the display region comprises a first display region and a second display region, and the second display region is located between the first display region and the non-display region;
a substrate;
a light-emitting device layer located on a side of the substrate, wherein the light-emitting device layer comprises light-emitting devices, each of the light-emitting devices comprises a first light-emitting device and a second light-emitting device, the first light-emitting device is located in the first display region, and the second light-emitting device is located in the second display region; and
light-blocking structures located on a side of the light-emitting device layer away from the substrate, wherein each of the light-blocking structures comprises a first light-blocking structure and a second light-blocking structure, the first light-blocking structure is provided adjacent to the first light-emitting device, and the second light-blocking structure is provided adjacent to the second light-emitting device;
wherein a thickness of the first light-blocking structure is greater than a thickness of the second light-blocking structure, or a height of the first light-blocking structure is higher than a height of the second light-blocking structure.
